(19) United States
(12) Patent Application Publication
(10) Pub. No.: US 2018/0298485 A1
(43) Pub. Date: Oct. 18, 2018

(54) EVAPORATION SYSTEM

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventor: Qinghua ZOU, Beijing (CN)

(21) Appl. No.: 15/844,495

(22) Filed: Dec. 15, 2017

(30) Foreign Application Priority Data
Apr. 13, 2017 (CN) 201710241120.4

(51) Int. Cl. C23C 14/12; C23C 14/54; H01L 51/00

(52) U.S. Cl. CPC C23C 14/12; C23C 14/542; H01L 2251/5338; H01L 51/001; C23C 14/548

(57) ABSTRACT

An evaporation system is disclosed, inclueding a feeding device, an evaporation device, and a storage device, wherein the feeding device comprises a feeding device housing which defines a feeding space; a feeding port which is arranged on the feeding device housing; a discharge port which is arranged on the feeding device housing and is away from the feeding port; and a propelling unit which is at least partially embedded in the feeding space, and is configured to push a raw material in the feeding space to move from the feeding port to the discharge port; wherein the evaporation device is connected with the feeding device; and wherein the storage device is connected with the feeding port of the feeding device.

### RELATED APPLICATIONS

The present application claims the benefit of Chinese Patent Application No. 201710241120.4, filed on Apr. 13, 2017, the entire disclosure of which is incorporated herein by reference.

### TECHNICAL FIELD

The present disclosure relates to the field of organic optoelectronic device, and particularly to an evaporation system.

### BACKGROUND

An organic device has been widely applied to the industrial field of organic semiconductor, and evaporation is a key process for fabricating the organic device. Currently, evaporation has become a mainstream process for an organic light emitting device (OLED). In the evaporation technique, under the principle of evaporation by heating, an organic material and metallic material are heated and vaporized, for forming layers such as an organic film, cathode, or the like.

With the development of a large size OLED, a chamber for organic evaporation becomes increasingly large, which thus poses more strict requirements the volume and vacuum degree of the organic evaporation chamber. In the current vacuum evaporation apparatus, when the evaporation material is used up, the chamber is generally opened and the vacuum is broken. The evaporation material is reloaded, and the chamber is vacuumed again. In another method, the chamber is provided with a plurality of heating sources. When the organic material in a heating source is running short, this heating source is replaced by another heating source.

However, there is still room for improving the existing evaporation system.

### SUMMARY

It is an objective of the present disclosure to alleviate or solve one or more of the above problem.

In view of this, in an aspect of the present disclosure, an evaporation system is provided. The evaporation system comprises: a feeding device, an evaporation device, and a storage device, wherein the feeding device comprises a feeding device housing which defines a feeding space; a feeding port which is arranged on the feeding device housing; a discharge port which is arranged on the feeding device housing and is away from the feeding port; and a propelling unit which is at least partially embedded in the feeding space, and is configured to push a raw material in the feeding space to move from the feeding port to the discharge port; wherein the evaporation device is connected with the feeding device; and wherein the storage device is connected with the feeding port of the feeding device. The evaporation system has at least one of the following advantages. The evaporation system can be fed in a continuous manner, and thus the production efficiency is improved. Feeding in a continuous manner ensures that the raw material fed into the evaporation system has excellent uniformity. The yield is improved. There is no raw material residual. This enables a stable evaporation rate.

In an embodiment of the present disclosure, the feeding device further comprises a first heating unit which is configured to heat the raw material in the feeding space. In this way, the production efficiency of the evaporation system is further improved.

In an embodiment of the present disclosure, the propelling unit further comprises: a propelling element which is at least partially embedded in the feeding space. In this way, the raw material is pushed from the feeding port to the discharge port, without raw material residuals. This reduces the cost of raw material (organic material), enables a stable evaporation rate, and improves yield.

In an embodiment of the present disclosure, the propelling unit further comprises: a speed controller which is connected with the propelling element and is configured to control a moving speed of the propelling element. In this way, the raw material is pushed at a constant speed from the feeding port to the discharge port, without raw material residuals. This reduces the cost of raw material (organic material), enables a stable evaporation rate, and improves yield.

In an embodiment of the present disclosure, the propelling element is a piston, a pusher arm, or a screw rod. The speed at which the material is pushed thus is further controlled.

In an embodiment of the present disclosure, the feeding device further comprises: a retrieving port which is arranged on the feeding device housing and communicates with the discharge port. In this way, residual organic material can be retrieved. The retrieved residual organic material is recycled. This reduces raw material residuals, and reduces the cost of organic material.

In an embodiment of the present disclosure, the feeding device further comprises at least one of: a first heat insulation unit which is connected with the first heating unit; and a first cooling unit which is connected with the first heating unit. The heating efficiency of the first heating unit thus is further improved.

In an embodiment of the present disclosure, the evaporation device further comprises: an evaporation device housing which defines an evaporation space; an evaporation feeding port which is arranged on the evaporation device housing and is connected with the discharge port of the feeding device; and an evaporation discharge port which is arranged on a surface of the evaporation device housing away from the evaporation feeding port. In this way, the production efficiency of the evaporation system comprising the evaporation device is further improved.

In an embodiment of the present disclosure, the evaporation device further comprises: a heat transfer plate which is arranged inside the evaporation space and is provided with an opening; and a second heating unit which is configured to heat the raw material inside the evaporation space. In this way, the temperature inside the evaporation device is uniformly distributed, and the temperature is adjustable. The evaporation rate is controlled, which enables a stable evaporation rate and improves yield.

In an embodiment of the present disclosure, at least a portion of the evaporation device housing is a cylindrical housing, and the heat transfer plate is arranged along the cylindrical housing in a radial direction. In this way, the production efficiency is further improved.

In an embodiment of the present disclosure, the second heating unit further comprises: a heating element which is arranged on an inner sidewall of the evaporation device housing. The heating element can heat organic material inside a chamber of the evaporation device, and adjust the temperature of organic material in the evaporation device. This enables a stable evaporation rate, and thus improves production efficiency.

In an embodiment of the present disclosure, the evaporation device further comprises at least one of the following units: a second heat insulation unit which is connected with the second heating unit, and a second cooling unit which is connected with the second heating unit. In this way, the heating efficiency is improved to prevent temperature from rising too high, and can improve operation efficiency.

In an embodiment of the present disclosure, the storage device further comprises: a funnel shaped storage silo which has a bottom part connected with the feeding port of the feeding device; and a third heating unit which is connected with the funnel shaped storage silo. The storage device has at least one of the following advantages. The funnel shaped storage silo can utilize the gravity to cause the organic material to flow towards the feeding device, which improves production efficiency. The volatile impurities in the organic material are removed, which improves yield.

In an embodiment of the present disclosure, the evaporation system further comprises: an evaporation device which comprises: an evaporation device housing which defines a vapor accommodating space; a vapor inlet which is arranged on the evaporation device housing and is connected with the evaporation discharge port of the evaporation device; at least one vapor outlet which is arranged on the evaporation device housing at a position corresponding with the vapor inlet, and which has at least one of hole shape, linear shape and planar shape. In this way, evaporation with a point source, a linear source or a planar source is realized by this system, which expands the evaporation modes of the system.

In an embodiment of the present disclosure, the feeding device is parallel or perpendicular with the evaporation device. In this way, the evaporation system can operate in a horizontal or vertical evaporation mode, so that the production efficiency and utilization ratio is improved.

In an embodiment of the present disclosure, the evaporation system is a vacuum evaporation system.

### BRIEF DESCRIPTION OF THE DRAWINGS

These and other aspects of the invention are apparent from and will be further elucidated, by way of example, with reference to the drawings, in which:

FIG. 1 shows a structural view for an evaporation system in an embodiment of the present disclosure;

FIG. 2 shows a structural view for a feeding device in an embodiment of the present disclosure;

FIG. 3 shows a structural view for a feeding device in another embodiment of the present disclosure;

FIG. 4 shows a structural view for a feeding device in yet another embodiment of the present disclosure;

FIG. 5 shows a structural view for a feeding device in yet another embodiment of the present disclosure;

FIG. 6 shows a structural view for an evaporation system in an embodiment of the present disclosure;

FIG. 7 shows a structural view for an evaporation device in an embodiment of the present disclosure;

FIG. 8 shows a structural view for an evaporation device in another embodiment of the present disclosure;

FIG. 9 shows a structural view for an evaporation device in yet another embodiment of the present disclosure;

FIG. 10 shows a structural view for an evaporation system in an embodiment of the present disclosure;

FIG. 11 shows a structural view for an evaporation system in another embodiment of the present disclosure;

FIG. 12 shows a partial structural diagram for an evaporation device in an embodiment of the present disclosure;

FIG. 13 shows a partial structural diagram for an evaporation device in another embodiment of the present disclosure;

FIG. 14 shows a partial structural diagram for an evaporation device in yet another embodiment of the present disclosure;

FIG. 15 shows a structural view for an evaporation system in an embodiment of the present disclosure; and

FIG. 16 shows a structural view for an evaporation system in another embodiment of the present disclosure.

### DETAILED DESCRIPTION OF EMBODIMENTS

This and other aspects of the present disclosure will now be described in more detail, with reference to the appended drawings showing embodiments of the disclosure.

Reference numerals: 100: feeding device; 110: feeding device housing; 120: feeding port; 130: discharge port; 140: feeding space; 150: propelling unit; 151: propelling element; 152: speed controller; 160: first heating unit; 170: retrieving port; 180: first heat insulation unit; 190: first cooling unit; 200: evaporation device; 210: evaporation device housing; 220: evaporation feeding port; 230: evaporation discharge port; 240: heat transfer plate; 250: second heating unit; 10: opening; 251: heating element; 260: second heat insulation unit; 270: second cooling unit; 300: storage device; 310: funnel shaped storage silo; 320: third heating unit; 400: evaporation device; 410: evaporation device housing; 420: vapor inlet; 430: vapor outlet; 431: hole shaped vapor outlet; 432: linear shaped vapor outlet; 433: planar shaped vapor outlet.

The inventor has found that the existing evaporation system commonly suffers from problems of raw material residuals in the evaporation source, difficulty in keeping a constant temperature for the evaporation material, difficulty in controlling the evaporation rate in a stable range. This further affects yield of product of the vacuum evaporation, decreases the production efficiency, and increases the production cost. The inventor further found that during fabricating a large size OLED, a large amount of organic evaporation material is needed, and it is required to evaporate alternately with two heating sources, or it is required to increase the capacity of the feeding device to feed all organic evaporation material in one time. During evaporation, the organic material in the heating source decreases gradually. When the heating source contains about 10% raw material, the heating rate can not be adjusted with the decrease in raw material. This results in an un-stable evaporation rate. If a push mechanism is arranged at the bottom part. The organic material at the bottom part is pushed to the evaporation chamber during evaporation. However, the organic material conducts heat, and most organic materials for evaporation are materials with meltbility. This design can hardly keep a stable temperature of the organic material to keep a stable evaporation rate. Therefore, this design also suffers from the problem of raw material residuals. The organic material is heated repeatedly at the early stage of evaporation. This causes change in the property of the raw material, so that the raw material can not be recycled. This causes raw material residuals, and increases the cost of organic material.

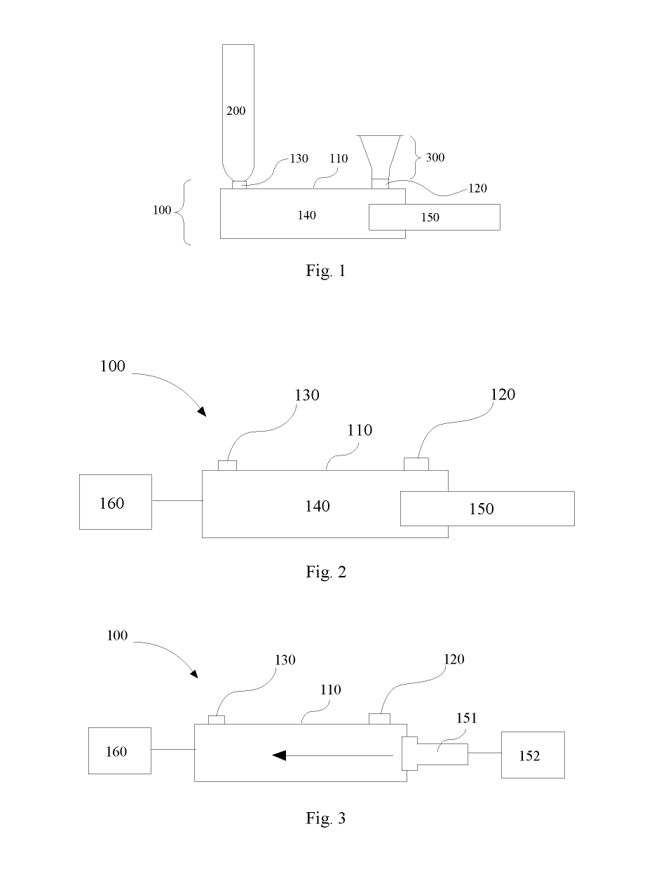

In an aspect of the present disclosure, the present disclosure provides an evaporation system. In an embodiment of the present disclosure, as shown in FIG. 1, the evaporation system comprises: a feeding device 100, an evaporation device 200 and a storage device 300. In an embodiment of the present disclosure, as shown in FIG. 2, the feeding device 100 comprises: a feeding device housing 110, a feeding port 120, a discharge port 130, a feeding space 140, and a propelling unit 150. The feeding space 140 is defined inside the feeding device housing 110. The feeding port 120 and the discharge port 130 are arranged on the feeding device housing 110. The discharge port 130 is arranged away from the feeding port 120. The propelling unit 150 is used to push the raw material which enters the feeding space 140 through the feeding port 120, and push the raw material to move toward the discharge port 130. In this way, after the raw material enters the feeding space 140, a propelling journey is provided inside the feeding space 140, so that the raw material is sufficiently heated in the feeding space 140. The propelling unit 150 is at least partially embedded in the feeding space 140, so that the propelling unit 150 pushes the raw material to move from the feeding port 120 to the discharge port 130. The evaporation system has at least one of the following advantages. The feeding device 100 of the evaporation system has a separate feeding space 140, so that the raw material is fed in a continuous manner. This ensures that the raw material fed into the evaporation system has excellent uniformity. The yield is improved. There is no raw material residual. This enables a stable evaporation rate.

In an embodiment of the present disclosure, the evaporation system is not limited to a specific type. For example, the evaporation system is a vacuum evaporation system. In this way, in the present embodiment, the storage device and the evaporation device is separated by the feeding device, so that each device has an individual chamber. In a vacuum environment, a lot of material can be stored in the storage device, without frequently breaking the vacuum environment to replenish material. The material in the storage device will not be affected by the temperature of evaporation device.

In an embodiment of the present disclosure, as shown in FIG. 2, the feeding device 100 further comprises a first heating unit 160. The first heating unit 160 is used to heat the raw material in the feeding space 140. In this way, the production efficiency of the evaporation system is further improved.

Units of the feeding device 100 will be described hereinafter with reference to specific embodiments of the present disclosure.

In an embodiment of the present disclosure, as shown in FIG. 3, the propelling unit 150 further comprises a propelling element 151. The propelling element 151 is at least partially embedded in the feeding space 140 (not shown), so that the raw material moves in a direction from the feeding port 120 to the discharge port 130 (as shown by the direction of arrow in the figure). It is understood by the person with ordinary skill in the art that, the propelling element 151 is not limited to any specific structure and type. For example, the propelling element 151 is a piston, a pusher arm or a screw rod. In an embodiment of the present disclosure, as shown in FIG. 3, the propelling unit 150 further comprises a speed controller 152. The speed controller 152 is connected with the propelling element 151, for controlling a speed at which the propelling element 151 drives the raw material to move in the feeding space 140. It will be understood by the person with ordinary skill in the art that the feeding device 100 is configured to supply the raw material (organic material) into the evaporation device. Thus, the feeding device 100 in the embodiment of the present disclosure can adjust the rate at which the discharge port 130 supplies the raw material, e.g., according to the rate by which the raw material decreases due to evaporation in the evaporation device. In this way, it is possible for the feeding port 120 to push the raw material to the discharge port 130 at a constant speed. Alternatively, the rate at which the discharge port 130 supplies the raw material is adjusted according to the evaporation rate in evaporation device, so that the total amount of raw material in the evaporation device keeps constant during evaporation. Since the feeding device 100 is provided with the propelling unit 150 as described above, the raw material which is supplied to the evaporation device is the raw material which is supplied from the discharge port 130, and the old raw material which previously stacked at the bottom of the evaporation device or the like is continuously pushed upward by the raw material at the discharge port 130. This can avoid raw material residuals. This reduces the cost of raw material (organic material), enables a stable evaporation rate, and improves yield.

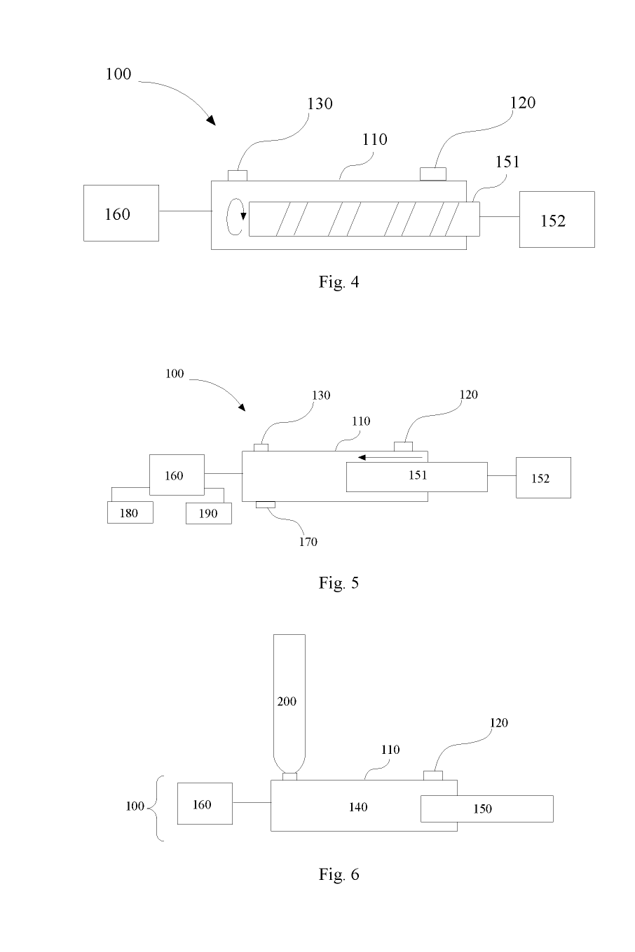

It will be appreciated by the person with ordinary skill in the art that the manner in which the propelling unit 150 pushes the raw material. For example, a piston is adopted as the propelling element 151. The piston is driven in a pneumatic manner to move in the feeding space 140, and thus to push the raw material. Alternatively, as shown in FIG. 3, a pusher arm is adopted as the propelling element 151. The pusher arm moves in the feeding space 140 (in the direction of arrow shown in the figure), so as to propel the raw material in a direction from the feeding port 120 to the discharge port 130. It will be appreciated by the person with ordinary skill in the art that, the piston or pusher arm can also move in a direction from the discharge port 130 to the feeding port 120, so that the piston or pusher arm is reset and ready to propel the next batch of raw material. The speed controller 152 is a pedometer, which controls the propelling element 151 in the form of the pusher arm to move toward the discharge port 130 (in the direction of arrow shown in the figure) at a predefined rate. Alternatively, as shown in FIG. 4, a screw rod is used as the propelling element, and the screw rod is rotated in the feeding space 140 (in the direction of arrow shown in the figure) to push the raw material to move.

In an embodiment of the present disclosure, the first heating unit 160 can control the temperature in the feeding space 140, namely, the temperature of the raw material which is supplied into the feeding space 140. In case it is required to heat the raw material which has been supplied into the feeding space 140, the first heating unit is started to pre-heat the raw material. In this way, the first heating unit 160 is used to control the temperature of the raw material, and increase the temperature of raw material which will be supplied to a subsequent processing device (e.g., the evaporation device). This can reduce the difference between the temperature of raw material in the feeding device 100 and the temperature of raw material in the evaporation chamber. As a result, this enables a stable evaporation rate in the subsequent stage. Moreover, the first heating unit 160 can control the temperature of raw material in the feeding device 100 to be lower than the evaporation temperature of the raw material. This prevents the large amount of raw material from staying in a high temperature environment for a long time, which would otherwise cause the raw material to deteriorate. The first heating unit 160 is used to control the temperature of raw material in the feeding space 140 in a range between room temperature and 200° C. It is noted that, in the present disclosure, the term “room temperature” shall be interpreted in a broad sense, and indicates a temperature that the raw material can reach via external heat exchange without additional heating or cooling. In an example, the room temperature is 0-40° C. In another example, the room temperature is 15° C. −30° C. In this way, it is possible to avoid the raw material from staying in the high temperature environment for a long time and thus deteriorating. In order to further improve the heating efficiency of the first heating unit 160, the feeding device 100 further comprises at least one of the following units: a first heat insulation unit 180, and a first cooling unit 190. The first heat insulation unit 180 is connected with the first heating unit 160, and the first cooling unit 190 is connected with the first heating unit 160. The first heat insulation unit 180 is arranged between the first cooling unit 190 and the first heating unit 160. The first heat insulation unit 180 prevents the first cooling unit 190 from directly contacting the first heating unit 160, and avoids loss in heat due to the direct contact therebetween, so as to improve the heating efficiency. For example, the first heat insulation unit 180 is a multiple-layer metal reflector sheet, and the first cooling unit 190 is a plurality of water cooling pipes. Thus the heating efficiency of the first heating unit 160 is further improved.

In an embodiment of the present disclosure, as shown in FIG. 5, in order to avoid that the raw material residuals at the discharge port 130 is not discharged from the feeding device 100 via the discharge port 130, and the raw material residuals are wasted, the feeding device 100 further comprises a retrieving port 170. The retrieving port 170 is arranged on the feeding device housing 110, and communicates with the discharge port 130. In this way, the raw material residuals at the discharge port 130 are retrieved through the retrieving port 170. For example, as shown in FIG. 4, when the feeding device housing 110 is arranged in a horizontal direction, the retrieving port 170 is positioned below the discharge port 130. When it is required to remove raw material residuals, the retrieving port 170 is opened, so that the raw material residuals are discharged from the feeding device 100 under gravity. The retrieved residual organic material is recycled. This can reduce raw material residuals, and decrease the cost of organic material.

In an embodiment of the present disclosure, as shown in FIG. 6, the evaporation system comprises the evaporation device 200. The evaporation device 200 is connected with the feeding device 100 as described above. The evaporation system has at least one of the following advantages. The organic material is supplied in a continuous manner, without opening the evaporation device for replenishing the raw material and breaking the vacuum degree, which improves the production efficiency. The yield of the system is improved. The raw material residuals are avoided, which reduces the cost of organic material.

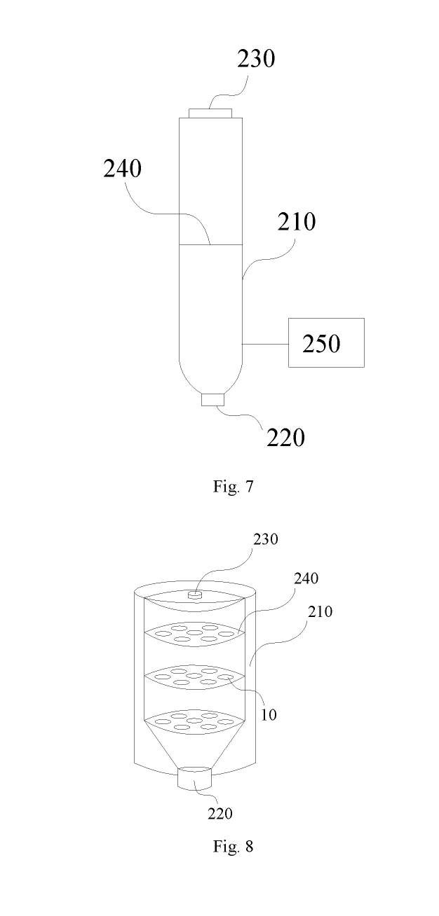

In an embodiment of the present disclosure, as shown in FIG. 7, the evaporation device 200 further comprises an evaporation device housing 210, an evaporation feeding port 220, and an evaporation discharge port 230. The evaporation device housing 210 defines an evaporation space. The evaporation feeding port 220 is arranged on the evaporation device housing 210. The evaporation feeding port 220 is connected with the discharge port 130 of the feeding device 100. The evaporation discharge port 230 is arranged on a surface of the evaporation device housing 210 away from the evaporation feeding port 220. In this way, the production efficiency of an evaporation system comprising the evaporation device 200 is further improved. In an embodiment of the present disclosure, as shown in FIG. 6, the evaporation device 200 further comprises a heat transfer plate 240 and a second heating unit 250. The heat transfer plate 240 is arranged inside the evaporation space. The heat transfer plate 240 is provided with an opening (not shown). The second heating unit 250 is connected with the evaporation device housing 210. In this way, the temperature inside the evaporation device 200 is uniformly distributed and the evaporation temperature is adjusted, so that a stable evaporation rate is provided. This can further improve the yield of the organic evaporation system.

In an embodiment of the present disclosure, in order to further improve the operation efficiency and effect of the evaporation device 200, the evaporation device housing 210 can at least partially be a cylindrical housing, and the heat transfer plate 240 is arranged along the cylindrical housing in a radial direction. In this case, the evaporation feeding port 220 and the evaporation discharge port 230 is position on a bottom surface and a top surface of the cylindrical housing, respectively, so that the raw material supplied by the feeding device 100 as described above is heated into vapor in the cylindrical housing, and the vapor is discharged from the evaporation device 200 through the evaporation discharge port 230. The heat transfer plate 240 is arranged in the radial direction in the path of vaporizing the raw material, so that the heat transfer plate 240 improves the heat conduction efficiency and keeps a uniform temperature in the evaporation space.

In an embodiment of the present disclosure, the heat transfer plate 240 is not limited in term of its number and arrangement manner. For example, as shown in FIG. 8, a plurality of heating plates 240 is arranged inside the cylindrical housing in a radial direction. In an embodiment of the present disclosure, the air vent 10 on the heating plate 240 is not limited in term of its number and arrangement manner, provided that the raw material or the vaporized raw material can pass through the air vent 10 and move in the evaporation space from the evaporation feeding port 220 to the evaporation discharge port 230. For example, each of the heat transfer plate 240 comprises a plurality of air vents 10 which are uniformly distributed.

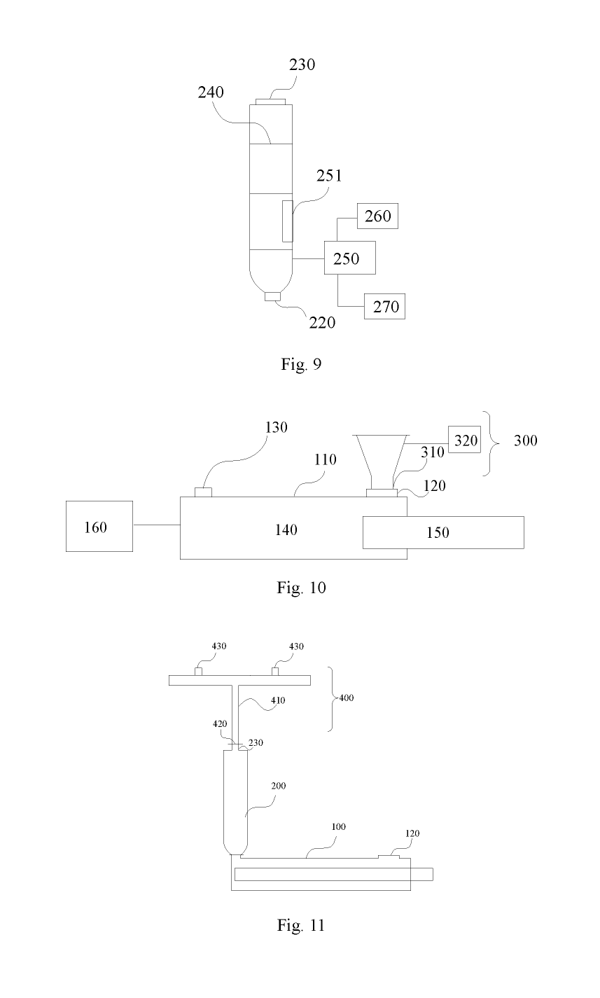

In an embodiment of the present disclosure, the evaporation device 200 is provided with a separate second heating unit 250 for heating the organic material in the chamber of the evaporation device 200. Thus, the temperature of organic material in the evaporation device 200 is adjusted, a stable evaporation rate is enabled, and this improves the production efficiency. As shown in FIG. 9, in order to further improve heating effect of the second heating unit 250, the second heating unit 250 further comprises a heating element 251 which is arranged on an inner sidewall of the evaporation device housing 210. In this way, the heating effect of the second heating unit 250 is further improved. It will be appreciated by the person with ordinary skill in the art that, organic material (raw material) in the evaporation device is set at a specific temperature according to the type of organic material, provided that the organic material is evaporated. For example, according to the type of raw material, the temperature of the organic material in the evaporation device 200 is adjusted to 200-500° C. In an embodiment of the present disclosure, the evaporation device 200 further comprises at least one of the following units: a second heat insulation unit 260, and a second cooling unit 270. The second heat insulation unit 260 is connected with the second heating unit 250, and the second cooling unit 270 is connected with the second heating unit 250. The second heat insulation unit 260 is arranged between the second cooling unit 270 and the second heating unit 250. The second heat insulation unit 260 improves the heating efficiency, prevents the second cooling unit 270 from directly contacting the second heating unit 250, which would lead to loss in heat. For example, the second heat insulation unit 260 is a multiple-layer metal reflector sheet. In this way, the heating efficiency of the second heating unit 250 is improved.

In an embodiment of the present disclosure, as shown in FIG. 10, the evaporation system comprises the storage device 300. The storage device 300 further comprises a funnel shaped storage silo 310 and a third heating unit 320. The funnel shaped storage silo 310 has a bottom part which is connected with the feeding port 120 of the feeding device 100 as described above. The third heating unit 320 is connected with the funnel shaped storage silo 310. The storage device 300 has at least one of the following advantages. The bottom part of the funnel shaped storage silo 310 is connected with the feeding port 120, so that the organic material can flow to the feeding device 100 under gravity as described above. This improves the production efficiency. The third heating unit 320 can separately control the temperature in the funnel shaped storage silo 310, and can remove volatile impurities in the organic material. This improves the yield of a product which subsequently fabricated from the raw material. For example, the temperature in the funnel shaped storage silo 310 is controlled in a range of between room temperature and 200 ° C. In this way, when it is required to remove volatile impurities in the organic material, the third heating unit 320 is started to heat the organic material. This also avoids a too high heating temperature, which may deteriorate the organic material.

In an embodiment of the present disclosure, as shown in FIG. 11, the evaporation system comprises an evaporation device 400. The evaporation device 400 further comprises an evaporation device housing 410, a vapor inlet 420, and a vapor outlet 430. The evaporation device housing 410 defines a vapor accommodating space. The vapor inlet 420 is arranged on the evaporation device housing 410, and is connected with the evaporation discharge port 230 of the evaporation device 200 as described above. The evaporation device 400 comprises at least one vapor outlet 430, which is arranged in the evaporation device housing 410 at a position corresponding with the vapor inlet 420. The vapor outlet 430 has a hole shape, a linear shape, or a planar shape. In this way, evaporation with a point source, a linear source or a planar source is realized by this system, which expands the evaporation modes of the system.

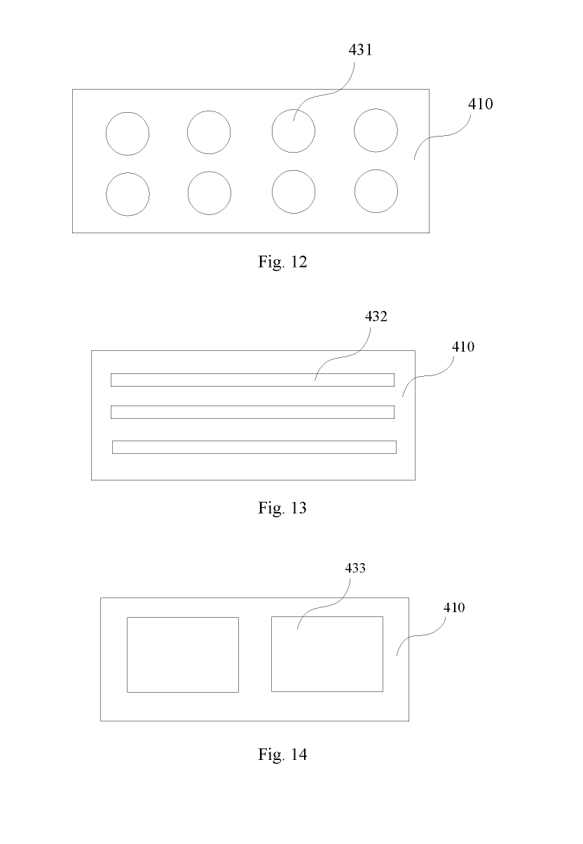

In an embodiment of the present disclosure, the vapor outlet 430 is not limited in term of its number, shape, and arrangement manner. For example, as shown in FIG. 12, a plurality of vapor outlets 430 are hole shaped vapor outlets 431. Alternatively, as shown in FIG. 13, the vapor outlets 430 are linear shaped vapor outlets 432. Alternatively, as shown in FIG. 14, the vapor outlets 430 are planar shaped vapor outlets 433. It is noted that the vapor outlets 430 are not limited in term of its number, and the number of the vapor outlets 430 in FIGS. 12-14 is exemplary. The vapor outlets 430 are not limited in term of their arrangement manner. The vapor outlets 430 can be distributed uniformly. Namely, the spacing between any two neighboring vapor outlets 430 is constant.

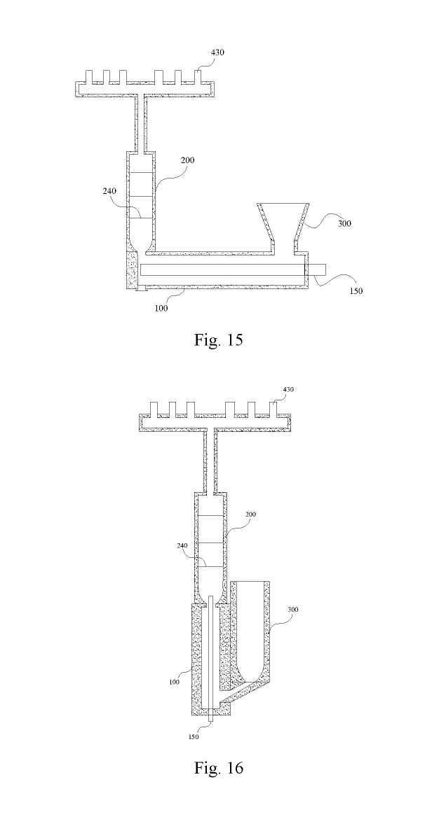

In an embodiment of the present disclosure, the feeding device 100 is parallel with the evaporation device 200. Alternatively, the feeding device 100 is perpendicular with the evaporation device 200. In an embodiment of the present disclosure, the feeding device 100 and the evaporation device 200 are not limited in term of their position relationship, provided that the feeding device 100 can supply the raw material into the evaporation device 200. For example, as shown in FIG. 15, the feeding device 100 is arranged in a horizontal direction. Alternatively, as shown in FIG. 16, the feeding device 100 is arranged in a vertical direction. In this way, by appropriately designing connections among the feeding device 100, the evaporation device 200, and the storage device 300, the organic evaporation system can realize horizontal evaporation or vertical evaporation. This improves the production efficiency and apparatus utilization ratio.

To sum up, the evaporation system according to embodiments of the present disclosure has at least one of the following advantages.

(1) Each device comprises an individual chamber. Thus, it is possible to prevent the material storing process, the material feeding process, and the evaporation process from affecting one another.

(2) Each device comprises an individual heating unit. Thus, the temperature of raw material in each device can be controlled separately, the temperature of raw material can be adjusted as needed, and it is possible to avoid organic raw material from staying in the high temperature environment for a long time which would otherwise cause loss of the raw material.

(3) The raw material supply rate and the heating evaporation rate can be accurately controlled. The evaporation rate in the system is constant, and the yield is improved.

(4) The feeding device 100 supplies the raw material by pushing. This avoids the raw material from stacking in the evaporation device 200, and the residual raw material in the feeding device 100 can be retrieved through the retrieving port 170 for recycling. This saves the raw material and reduces cost.

Apparently, the person with ordinary skill in the art can make various modifications and variations to the present disclosure without departing from the spirit and the scope of the present disclosure. In this way, provided that these modifications and variations of the present disclosure belong to the scopes of the claims of the present disclosure and the equivalent technologies thereof, the present disclosure also intends to encompass these modifications and variations.

What is claimed is:

1. An evaporation system, comprising: a feeding device, an evaporation device, and a storage device,
wherein the feeding device comprises a feeding device housing that defines a feeding space; a feeding port that is arranged on the feeding device housing; a discharge port that is arranged on the feeding device housing and is away from the feeding port; and a propelling unit that is at least partially embedded in the feeding space, and is configured to push a raw material in the feeding space to move from the feeding port to the discharge port;
wherein the evaporation device is connected with the feeding device; and
wherein the storage device is connected with the feeding port of the feeding device.

2. The evaporation system of claim 1, wherein the feeding device further comprises: a first heating unit that is configured to heat the raw material in the feeding space.

3. The evaporation system of claim 1, wherein the propelling unit further comprises: a propelling element that is at least partially embedded in the feeding space.

4. The evaporation system of claim 3, wherein the propelling unit further comprises: a speed controller that is connected with the propelling element and is configured to control a moving speed of the propelling element.

5. The evaporation system of claim 1, wherein the feeding device further comprises: a retrieving port that is arranged on the feeding device housing and communicates with the discharge port.

6. The evaporation system of claim 1, wherein the feeding device further comprises: a first heat insulation unit that is connected with the first heating unit.

7. The evaporation system of claim 1, wherein the feeding device further comprises: a first cooling unit that is connected with the first heating unit.

8. The evaporation system of claim 1, wherein the evaporation device further comprises:
an evaporation device housing that defines an evaporation space;
an evaporation feeding port that is arranged on the evaporation device housing and is connected with the discharge port of the feeding device; and
an evaporation discharge port that is arranged on a surface of the evaporation device housing away from the evaporation feeding port.

9. The evaporation system of claim 8, wherein the evaporation device further comprises:
a heat transfer plate that is arranged inside the evaporation space and is provided with an opening; and
a second heating unit that is configured to heat the raw material inside the evaporation space.

10. The evaporation system of claim 8, wherein at least a portion of the evaporation device housing is a cylindrical housing, and the heat transfer plate is arranged along the cylindrical housing in a radial direction.

11. The evaporation system of claim 8, wherein the second heating unit further comprises a heating element that is arranged on an inner sidewall of the evaporation device housing.

12. The evaporation system of claim 8, wherein the evaporation device further comprises:
a second heat insulation unit that is connected with the second heating unit.

13. The evaporation system of claim 8, wherein the evaporation device further comprises:
a second cooling unit that is connected with the second heating unit.

14. The evaporation system of claim 1, wherein the storage device further comprises:
a funnel shaped storage silo that has a bottom part connected with the feeding port of the feeding device; and
a third heating unit that is connected with the funnel shaped storage silo.

15. The evaporation system of claim 1, further comprising:
an evaporation device that comprises:
an evaporation device housing that defines a vapor accommodating space;
a vapor inlet that is arranged on the evaporation device housing and is connected with the evaporation discharge port of the evaporation device;
at least one vapor outlet that is arranged on the evaporation device housing at a position corresponding with the vapor inlet, and that has at least one of hole shape, linear shape and planar shape.

16. The evaporation system of claim 1, wherein the feeding device is parallel with the evaporation device.

17. The evaporation system of claim 1, wherein the feeding device is perpendicular with the evaporation device.

18. The evaporation system of claim 1, wherein the evaporation system is a vacuum evaporation system.
